(19) United States
(12) Patent Application Publication
(10) Pub. No.: US 2025/0379154 A1
(43) Pub. Date: Dec. 11, 2025

(54) PACKAGE STRUCTURE AND MANUFACTURING METHOD THEREOF

(71) Applicant: Powertech Technology Inc., Hsinchu County (TW)

(72) Inventor: Shang-Yu Chang Chien, Hsinchu County (TW)

(73) Assignee: Powertech Technology Inc., Hsinchu County (TW)

(21) Appl. No.: 19/031,154

(22) Filed: Jan. 17, 2025

(30) Foreign Application Priority Data
Jun. 7, 2024 (TW) 113121370

(51) Int. Cl. H01L 23/538; H01L 21/48; H01L 23/00; H01L 23/14; H01L 23/31; H01L 23/48; H01L 25/00; H01L 25/03

(52) U.S. Cl. CPC H01L 23/5385; H01L 21/4846; H01L 23/5386; H01L 25/03; H01L 25/50; H01L 23/147; H01L 23/3135; H01L 23/481; H01L 24/13; H01L 2224/13025

(57) ABSTRACT

Disclosed is a packaging structure including a first chip, a second chip, multiple fourth chips, a first redistribution layer, a second redistribution layer, a third redistribution layer, a first dielectric body, a second dielectric body, and a conductive member. The first chip is disposed between the first redistribution layer and the third redistribution layer. The conductive member is disposed between the first redistribution layer and the second redistribution layer. The second redistribution layer is electrically connected to the first chip by the conductive member and the first redistribution layer, and is disposed between the second chip and the fourth chip. Two fourth chips are electrically connected to each other by the second redistribution layer and the second chip. The first dielectric body covers the second chip, the first redistribution layer, the second redistribution layer, and the conductive member. The second dielectric body covers the second redistribution layer.

### CROSS-REFERENCE TO RELATED APPLICATION

This application claims the priority benefit of Taiwan application serial no. 113121370, filed on Jun. 7, 2024. The entirety of the above-mentioned patent application is hereby incorporated by reference herein and made a part of this specification.

### BACKGROUND

### Technical Field

The disclosure relates to a package structure and a manufacturing method thereof, and in particular to a package structure with a plurality of heterogeneous chips being integrated and a manufacturing method thereof.

### Description of Related Art

With the advancement of science and technology, electronic products have also become more diversified in line with market demand. In order to meet the diverse demands for electronic products, a plurality of chips are often necessary to be integrated into a single package structure. For a package structure with a plurality of chips, how to make the package structure smaller in size but still has better quality or performance is actually a research topic.

### SUMMARY

The disclosure provides a package structure and a manufacturing method thereof. The package structure may have smaller size and better quality or performance.

A package structure of the disclosure includes a first chip, at least one second chip, multiple fourth chips, a first redistribution layer, a second redistribution layer, a third redistribution layer, a first dielectric body, a second dielectric body, and a conductive member. The first chip is disposed between the first redistribution layer and the third redistribution layer. The conductive member is disposed between the first redistribution layer and the second redistribution layer, and the second redistribution layer is electrically connected to the first chip by the conductive member and the first redistribution layer. The second redistribution layer is disposed between the second chip and the fourth chips. At least two of the fourth chips are electrically connected to each other by the second redistribution layer and the second chip. The first dielectric body at least covers the second chip, the first redistribution layer, the second redistribution layer, and the conductive members. The second dielectric body at least covers the second redistribution layer.

A manufacturing method of a package structure of the disclosure includes the following steps. A carrier is provided. A first redistribution layer is formed on the carrier. At least one second chip is disposed on the first redistribution layer. A first dielectric body is formed. A second redistribution layer is formed on the first dielectric body. A plurality of fourth chips are disposed on the second redistribution layer. A second dielectric body is formed. The carrier is cut to form a first chip. The first chip is disposed between the first redistribution layer and a third redistribution layer. A conductive member is disposed between the first redistribution layer and the second redistribution layer. The second redistribution layer is electrically connected to the first chip by the conductive member and the first redistribution layer. The second redistribution layer is disposed between the second chip and the fourth chips. At least two of the fourth chips are electrically connected to each other by the second redistribution layer and the second chip. The first dielectric body at least covers the second chip, the first redistribution layer, the second redistribution layer, and the conductive members. The second dielectric body at least covers the second redistribution layer.

Based on the above, the package structure of the disclosure may have a smaller size. Moreover, the package structure may have better quality or performance by the arrangement of the corresponding devices/components (chips, redistribution layers, dielectric bodies, and/or conductive members).

### BRIEF DESCRIPTION OF THE DRAWINGS

FIG. 1A to FIG. 1J are schematic partial cross-sectional views of a partial manufacturing method of a package structure according to an embodiment of the disclosure.

FIG. 1K is a schematic partial cross-sectional view of a package structure according to an embodiment of the disclosure.

FIG. 2 is a partial top view of a package structure according to an embodiment of the disclosure.

### DESCRIPTION OF THE EMBODIMENTS

Directional terms (e.g., up, down, top, and bottom) as used herein are used pictorially by reference only and are not intended to imply an absolute orientation. In addition, for clarity of illustration, some film layers or components may be omitted in the drawings.

Unless clearly stated otherwise, any method described herein is in no way intended to be interpreted as requiring the steps to be performed in a specific order.

The disclosure is more fully described with reference to the drawings of the embodiment. However, the disclosure may be embodied in various forms and should not be limited to the embodiments described herein. The thicknesses of layers and regions in the drawings are enlarged for clarity. The same or similar reference numerals denote the same or similar components, and the repeated descriptions are not repeated in the following paragraphs.

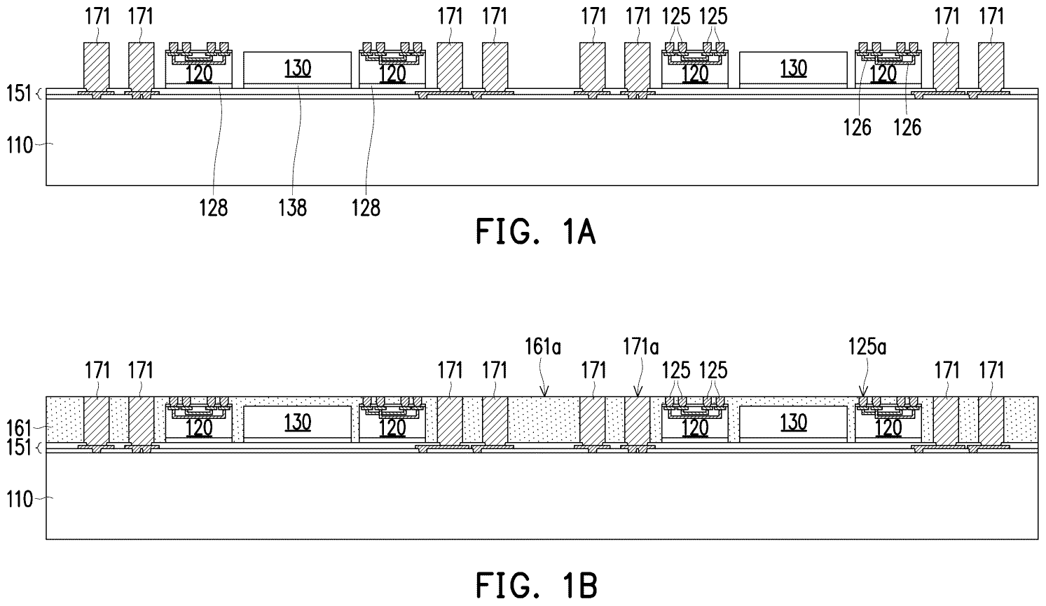

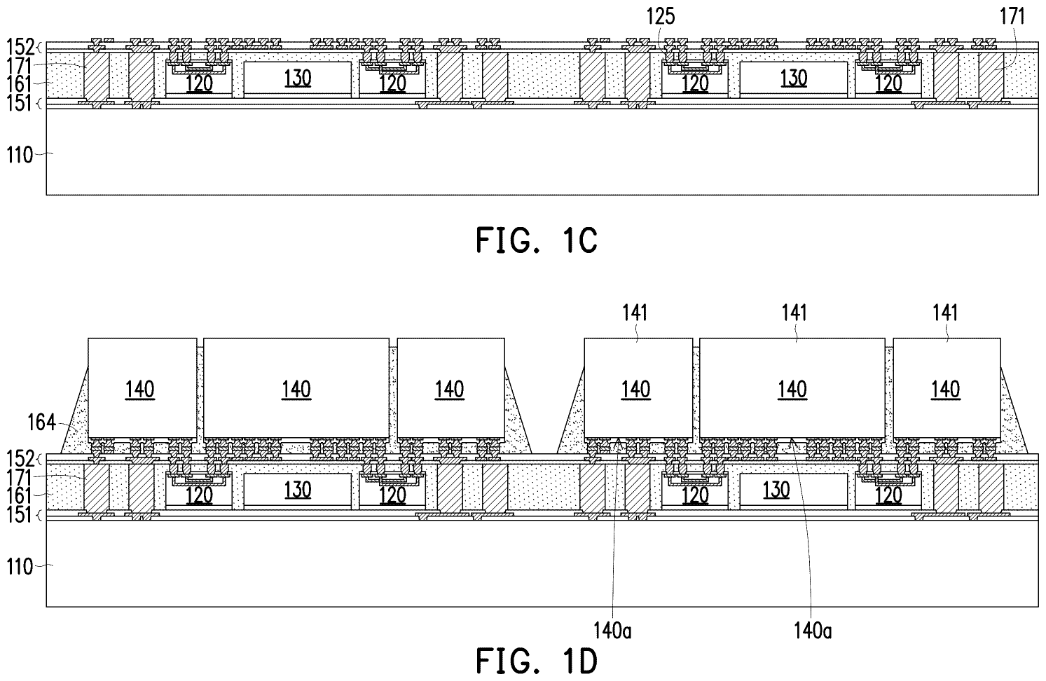

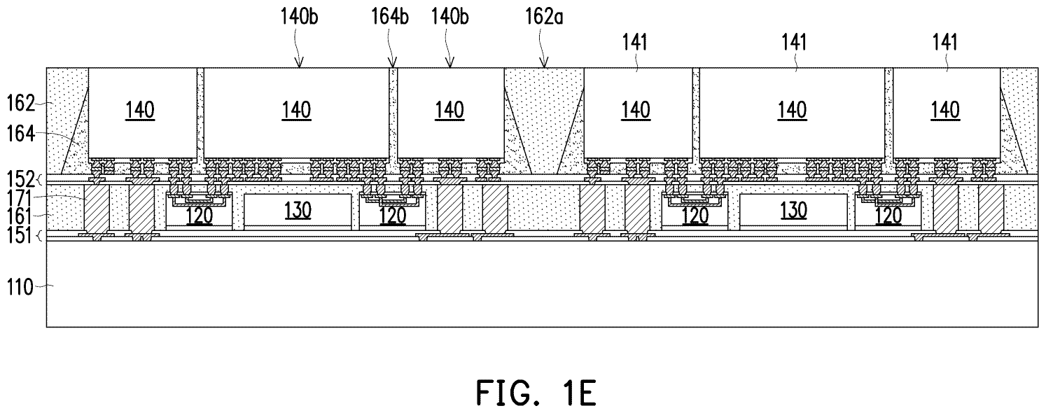

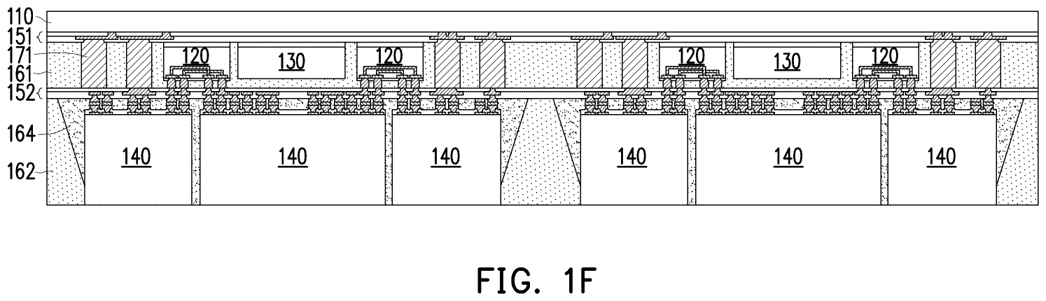

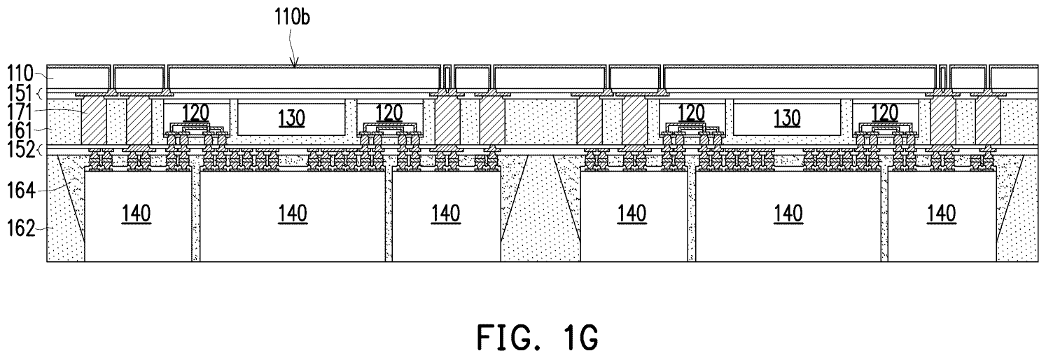

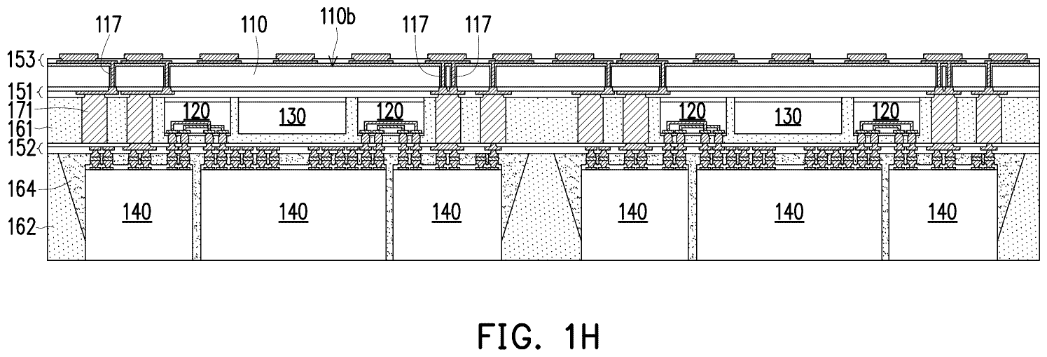

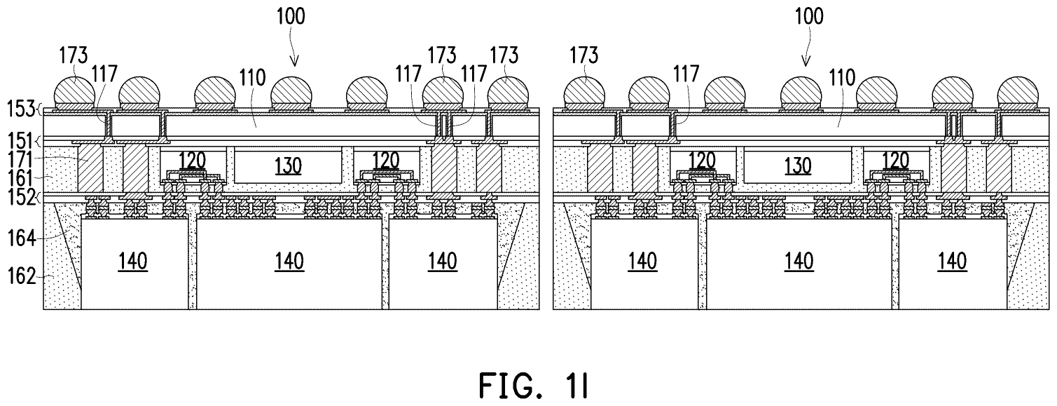

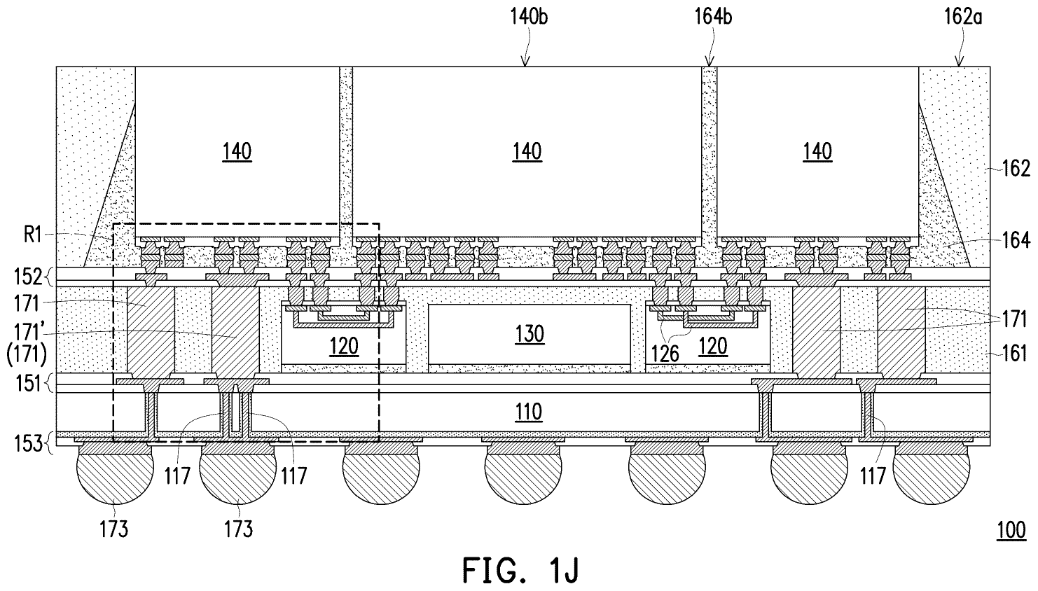

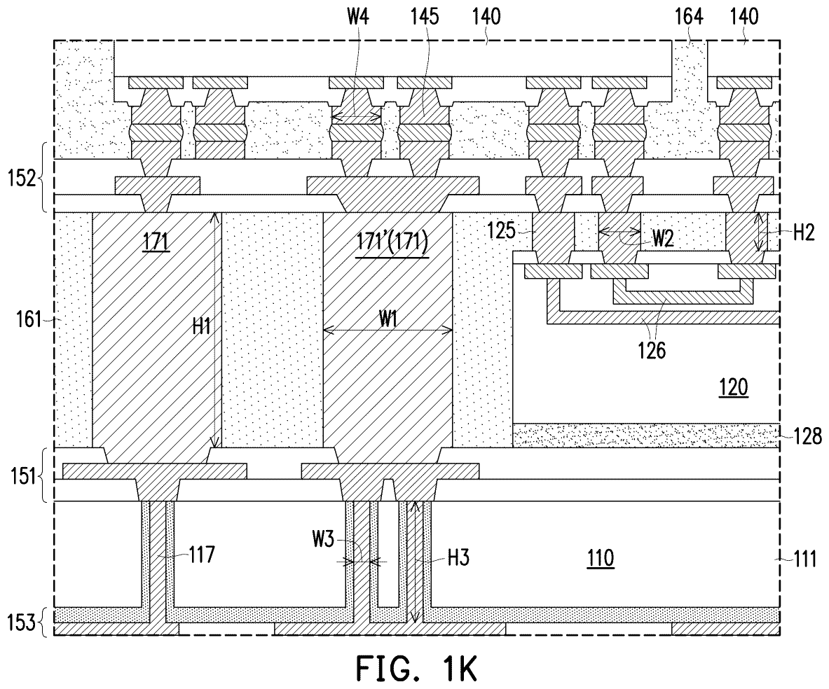

FIG. 1A to FIG. 1J are schematic partial cross-sectional views of a partial manufacturing method of a package structure according to an embodiment of the disclosure.

Referring to FIG. 1A, a carrier 110 is provided. In subsequent processes, the carrier 110 must at least be adaptable for carrying structures or components formed thereon.

The carrier 110 may be made of glass, wafer, ceramic, or other appropriate materials. For example, the carrier 110 may include bare glass, bare wafer, blanket wafer, or the like. In an embodiment, the carrier 110 may be a silicon wafer having a corresponding device region, and a device in the device region may include an active device (such as a transistor) and a passive device (such as a resistor, a capacitor, or an inductance) and/or a corresponding circuit (such as an interconnection) formed on and/or embedded therein. In an embodiment, the carrier 110 may be glass, and a corresponding electronic device (such as a thin film transistor (TFT)) and/or the corresponding circuit may be formed on the aforementioned glass in an appropriate manner.

Referring to FIG. 1A, a first redistribution layer 151 is formed on the carrier 110. The first redistribution layer 151 may be formed by an appropriate semiconductor process (such as deposition, plating, etching and/or other appropriate methods). The first redistribution layer 151 may include a corresponding circuit layer (not labeled, which may be a frame region including diagonal lines of the first redistribution layer 151 as shown in FIG. 1A or a drawing similar thereof) and an insulating layer (not labeled, which may be a frame blank region of the first redistribution layer 151 as shown in FIG. 1A or a drawing similar thereof). The layout design of the first redistribution layer 151 may be adjusted according to design requirements, and is not limited in the disclosure.

In addition, in order to make the drawings concise and clear, the circuit layer and the insulating layer of the first redistribution layer 151 are not directly labeled in FIG. 1A or other similar drawings. However, in FIG. 1A or other similar drawings, the frame region having diagonal lines in the first redistribution layer 151 may be the corresponding circuit layer included therein.

In an embodiment, if there is a corresponding electronic device (such as an active device, a passive device, or a circuit device) in or on the carrier 110, the corresponding circuit in the first redistribution layer 151 may be electrically connected to the aforementioned electronic device.

Referring to FIG. 1A continuously, a corresponding conductive member 171 is formed or disposed on the first redistribution layer 151. A corresponding circuit in the first redistribution layer 151 may be electrically connected to the corresponding conductive member 171.

In an embodiment, the conductive member 171 may include a pre-formed conductive pillar. For example, the preformed conductive pillar may be disposed on the first redistribution layer 151.

In an embodiment, the conductive member 171 may be formed by the appropriate semiconductor process (such as deposition, plating, etching, and/or other appropriate methods). For example, a corresponding seed layer may be formed on the first redistribution layer 151 first; then, a patterned mask layer is formed on the aforementioned seed layer, and exposes a portion of the seed layer; then, a plating layer is formed on the exposed portion of the seed layer; and then, the patterned mask layer and other portion of the seed layer not covered by the plating layer are removed. In this way, the remaining portion of the seed layer and the plating layer disposed thereon may constitute a corresponding conductive member 171.

Referring to FIG. 1A continuously, a plurality of second chips 120 are disposed on the first redistribution layer 151.

In an embodiment, one side of the second chip 120 may include a plurality of chip connectors 125. The chip connector 125 may include, for example, a conductive pillar or a conductive bump, but the disclosure is not limited thereto. At least two of the chip connectors 125 in a single second chip 120 may be electrically connected to each other by a corresponding circuit 126 in the second chip 120. It is worth noting that in FIG. 1A or other similar drawings, the circuit 126 in the second chip 120 is only schematically shown. The aforementioned circuit 126 may include an interconnect in back end of line (BEOL), a chip redistribution routing (such as a fan-in RDL), or a combination thereof, but the disclosure is not limited thereto.

In an embodiment, the second chip 120 may be a passive chip. The passive chip is a chip that does not include any active device (such as a transistor). In an embodiment, the second chip 120 may be referred as a bridge chip.

Referring to FIG. 1A continuously, at least one third chip 130 is disposed on the first redistribution layer 151. The second chip 120 and the third chip 130 may be heterogeneous chips.

In an embodiment, the third chip 130 may be a dummy chip. However, it is worth noting that the “dummy” of the dummy chip herein may only mean that the chip does not actually participate in the transmission of signals. However, the third chip 130, which is referred as the dummy chip, may still have structurally supporting, adjusting structural warpage during an process, shielding (such as electromagnetic interference shielding (EMI shielding)), performing heat transfer, or other appropriate purposes. For example, the third chip 130 that may be used for structurally supporting or adjusting structural warpage during a process (but may also include other purposes) may be referred as a structure chip.

It is worth noting that the disclosure does not limit the order of forming or disposing the conductive member 171, disposing the second chip 120, and disposing the third chip 130. For example, the conductive member 171 may be formed or disposed first, and then the second chip 120 and/or the third chip 130 may be disposed. For example, the second chip 120 and the third chip 130 may be disposed together by a corresponding same chip process.

In an embodiment, there may be a corresponding chip adhesion layer 128 between the second chip 120 and the first redistribution layer 151, and/or, there may be a corresponding chip adhesion layer 138 between the third chip 130 and the first redistribution layer 151.

Referring to FIG. 1A and FIG. 1B, a first dielectric body 161 covering the conductive member 171, the second chip 120, and the third chip 130 is formed. The first dielectric body 161 may expose a portion of the conductive member 171 and a portion of the second chip 120. The first dielectric body 161 may at least laterally cover the conductive member 171 and the second chip 120.

In an embodiment, the first dielectric body 161 is, for example, a molding compound. The molding compound may include, but is not limited to, epoxy. For example, polymer may be formed on the first redistribution layer 151 by a molding process, a coating process, or other appropriate methods. The aforementioned polymer may cover the conductive member 171, the second chip 120, and the third chip 130. The gelled or uncured polymer is then cured or pre-cured. Afterwards, if necessary, a portion of the conductive member 171 and a portion of the second chip 120 (such as a corresponding chip connector 125 in the second chip 120) may be exposed by an appropriate removal process to form a corresponding first dielectric body 161.

In a manufacturing method not shown, the first dielectric body 161 may be formed of photo imageable dielectric (PID) material. Moreover, a portion of the photo imageable dielectric material may be removed by the appropriate process to form an opening exposing a portion of the first redistribution layer 151. Afterwards, a conductive material is filled into the aforementioned opening to form a conductive member similar to the conductive member 171 and a corresponding first dielectric body 161.

In an embodiment, a first dielectric surface 161a of the first dielectric body 161, a top surface 125a of the chip connector 125 (if any), and/or a top surface 171a of the conductive member 171 are basically coplanar by chemical mechanical polishing (CMP), mechanical grinding, etching, or other appropriate planarizing processes.

Referring to FIG. 1B to FIG. 1C, a second redistribution layer 152 is formed on the first dielectric body 161. The second redistribution layer 152 may include a corresponding circuit layer (not labeled, which may be a frame region including diagonal lines of the second redistribution layer 152 as shown in FIG. 1C or a drawing similar thereof) and an insulating layer (not labeled, which may be a frame blank region of the second redistribution layer 152 as shown in FIG. 1C or a drawing similar thereof). The second redistribution layer 152 may be electrically connected to the first redistribution layer 151 and/or the second chip 120. For example, a corresponding circuit in the second redistribution layer 152 and a corresponding circuit in the first redistribution layer 151 may be electrically connected by a corresponding conductive member 171. For example, a corresponding circuit in the second redistribution layer 152 may be electrically connected to the corresponding chip connector 125 in the second chip 120. The layout design of the second redistribution layer 152 may be adjusted according to design requirements, and is not limited in the disclosure.

In addition, in order to make the drawings concise and clear, the circuit layer and insulating layer of the second redistribution layer 152 are not directly labeled in FIG. 1C or other similar drawings. However, in FIG. 1C or other similar drawings, the frame region having diagonal lines in the second redistribution layer 152 may be a corresponding circuit layer included therein.

In an embodiment, a topmost circuit layer (that is, a circuit layer furthest from the carrier 110 in a thickness direction) in the second redistribution layer 152 may include a bonding pad. In a subsequent step, the bonding pad may be adapted to bond with other electronic devices.

In an embodiment, the second redistribution layer 152 may be referred as a fan-out RDL.

Referring to FIG. 1C to FIG. 1D, a plurality of fourth chips 140 are disposed on the second redistribution layer 152. The fourth chip 140 may be an active chip. The active chip is a chip including an active device (such as a transistor).

The fourth chip 140 may be connected to a corresponding circuit in the second redistribution layer 152 in an appropriate manner. For example, an active surface 140a of the fourth chip 140 may face the second redistribution layer 152, and the fourth chip 140 may make a chip connector 145 (shown in FIG. 1K) thereof electrically connected to a corresponding bonding pad in the second redistribution layer 152 by flip chip bonding.

Please continue to refer to FIG. 1D. After the fourth chips 140 are disposed on the second redistribution layer 152, a filling layer 164 may be formed between any one of the fourth chips 140 and the second redistribution layer 152. The filling layer 164 is formed, for example, by capillary underfill (CUF) or other appropriate filling colloid. For example, the filling colloid may at least be filled between the fourth chips 140 and the second redistribution layer 152, and may further cover a portion of a side wall of the fourth chips 140; then, a corresponding filling layer 164 may be formed by an appropriate curing method.

In an embodiment not shown, it is not ruled out that a device (such as an integrated passive device (IPD)) different from the fourth chip 140 is disposed on the second redistribution layer 152. The aforementioned device may be electrically connected to a corresponding circuit in the second redistribution layer 152.

In subsequent steps, the filling layer 164 may improve the bonding between the fourth chips 140 and the second redistribution layer 152.

Referring to FIG. 1D to FIG. 1E, a second dielectric body 162 is formed, the fourth chips 140 are thinned, and the second dielectric bulk 162 may expose the fourth chips 140. It is worth noting that the disclosure does not limit the order between forming the second dielectric body 162 and thinning the fourth chips 140.

In an embodiment, a material and/or a forming method of the second dielectric body 162 may be the same or similar to that of the first dielectric body 161. For example, polymer may be formed on the second redistribution layer 152 by a molding process, a coating process, or other appropriate methods. The gelled or uncured polymer is then cured or pre-cured. Afterwards, the cured or pre-cured polymer may expose the fourth chips 140 by the appropriate removal process. Moreover, during the aforementioned removal process, the fourth chip 140 may be thinned by removing a portion (for example, a portion of a silicon material 141 of the chip) of the fourth chips 140. Since the structure on the carrier 110 as shown in FIG. 1D already has a considerable thickness, and the fourth chips 140 have been fixed on the second redistribution layer 152, the fourth chips 140 may be easily thinned to an appropriate thickness. In this way, the overall thickness of the package structure (such as a package structure 100 described later) may be reduced. In addition, for the simplicity and the function of the fourth chips 140 after thinning has no obvious impact, the fourth chips 140 before and after thinning are represented by the same reference numeral.

In an embodiment, during the process of thinning the fourth chips 140, a portion of the filling layer 164 may be removed.

In an embodiment, a material of the second dielectric body 162 is different from a material of the filling layer 164, and a contact section between the second dielectric body 162 and the filling layer 164 may have an interface formed by the different materials.

In an embodiment, a third dielectric surface 162a of the second dielectric body 162, a back surface 140b of the fourth chip 140, and/or a top surface 164b of the filling layer 164 (if any) are basically coplanar by CMP, mechanical grinding, etching, or other appropriate planarizing processes.

In an embodiment, a structure as shown in FIG. 1E is formed, and may be flipped upside down to perform subsequent steps (such as the steps shown in FIG. 1F).

Referring to FIG. 1E to FIG. 1F, the appropriate removal process may be performed to remove a portion of the carrier 110, so that the carrier 110 is thinned. For example, the structure shown in FIG. 1E may be flipped upside down, and the carrier 110 may be thinned by the appropriate removal process (such as the CMP process, the mechanical polishing process, or the etching process) to form the structure of the carrier 110 as shown in FIG. 1F.

Since the structure on the carrier 110 as shown in FIG. 1E already has a considerable thickness, and the devices in the structure and/or the structure and the carrier 110 have been well fixed, the carrier 110 may be easily thinned to an appropriate thickness. In this way, the overall thickness of the package structure (such as the package structure 100 described later) may be reduced. In addition, for the simplicity and the function of the carrier 110 after thinning has no obvious impact, the carrier 110 before and after thinning are represented by the same reference numeral.

In an embodiment, since the structure as shown in FIG. 1F still has considerable thickness as a whole, and the devices in the structure have been well fixed, the structure as shown in FIG. 1F does not need to be placed on another carrier for structural support and may be directly used for subsequent processes. However, it is worth noting that the structure shown in FIG. 1F does not exclude being placed on a functional carrier adaptable for other purposes. For example, the structure shown in FIG. 1F may still be placed on a carrier (such as a tray or a holder) adaptable for transportation or temporary placement.

Referring to FIG. 1F to FIG. 1G, an opening may be formed from a back surface 110b of the carrier 110 by etching or other appropriate methods. The opening may expose a corresponding circuit.

For example, if the carrier 110 already has a corresponding circuit, the opening may expose a portion of the carrier 110 corresponding to the circuit. For another example, if the carrier 110 does not have a corresponding circuit, the opening may expose a portion of the circuit layer in the first redistribution layer 151 closest to the carrier 110.

Please continue to refer to FIG. 1G. In an embodiment, after the opening is formed, a corresponding insulating layer (not labeled, which may be a frame region including dense dots) may be formed by deposition, etching, and/or other appropriate methods). The insulating layer may cover the back surface 110b of the carrier 110 and a side wall of the opening, and the insulating layer may expose the exposed circuit corresponding to the opening.

It is worth noting that if the carrier 110 already has good insulation or dielectric properties, the formation of the insulating layer may be omitted (however, it does not rule out that the insulating layer may still be formed). For example, if a material of the carrier 110 is insulating or dielectric glass or ceramic, the formation of the insulating layer may be omitted.

Referring to FIG. 1G to FIG. 1H, after the opening (or the insulating layer) exposing a corresponding circuit is formed, a corresponding conductive layer (not labeled, which may be a frame region including diagonal lines) may be formed by deposition, plating, etching, and/or other appropriate methods. The conductive layer includes, for example, a corresponding seed layer and a corresponding plating layer, but the disclosure is not limited thereto. A portion of the conductive layer and the corresponding insulating layer disposed within the opening may be referred to as a conductive through via 117. The portion of the conductive layer disposed on the back surface 110b of the carrier 110 may be referred as a circuit layer. That is, a conductive portion of the conductive through via 117 and a conductive portion of the circuit layer may be the same film layer. Afterwards, a corresponding insulating layer (not labeled, which may be a frame blank region of the third redistribution layer 153 as shown in FIG. 1H or a drawing similar thereof) and the circuit layer (not labeled, which may be a frame region including diagonal lines of the third redistribution layer 153 as shown in FIG. 1H or a drawing similar thereof) may further be formed on the aforementioned circuit layer by conventional semiconductor processes (such as film lamination, coating, deposition, plating, etching, and/or other appropriate methods). The circuit layer and the insulating layer disposed on the back surface 110b of the carrier 110 may constitute a third redistribution layer 153. In addition, for simplicity, the carrier 110 having the conductive through vias 117 is still represented by the same reference numeral.

The conductive through via 117 may have different names according to the material of the carrier 110, but the disclosure is not limited thereto. For example, if the carrier 110 is made of silicon, a corresponding conductive through via 117 may be referred as a through silicon via (TSV). For example, if the carrier 110 is made of glass, a corresponding conductive through via 117 may be referred as a through glass via (TGV). For example, if the carrier 110 is made of ceramic, a corresponding conductive through via 117 may be referred as a through ceramic via (TCV). For example, if the carrier 110 is made of polymer, a corresponding conductive through via 117 may be referred as a through polymer via (TPV).

In an embodiment, a topmost circuit layer (that is, a circuit layer farthest from the carrier 110 in the thickness direction) in the third redistribution layer 153 may include a bonding pad. In subsequent steps, the bonding pad may be adapted to bond with another electronic device.

In addition, in order to make the drawings concise and clear, the circuit layer and the insulating layer of the third redistribution layer 153 are not directly shown in FIG. 1H or other similar drawings. However, in FIG. 1H or other similar drawings, the frame region having diagonal lines in third redistribution layer 153 may be a corresponding circuit layer included therein.

Referring to FIG. 1H to FIG. 1I, a plurality of conductive terminals 173 may be formed on the circuit layer of the third redistribution layer 153. The conductive terminal 173 may be electrically connected to the carrier 110 by a corresponding circuit in the third redistribution layer 153/or a corresponding circuit disposed on the carrier 110. In addition, for clarity, not all conductive terminals 173 are labeled one by one in FIG. 1I or other similar drawings.

The conductive terminal 173 may be a conductive pillar, a solder ball, a conductive bump, an electroplated copper pillar bump, a conductive terminal with other forms or shapes, or a combination thereof. The conductive terminal 173 may be formed by electroplating, deposition, ball placement, reflow, and/or other appropriate processes.

Please continue to refer to FIG. 1I. In this embodiment, a plurality of package structures 100 may be formed by a singulation process. The single process may include, for example, a dicing process/cutting process to cut through the carrier 110, a corresponding redistribution layer (such as the first redistribution layer 151, the second redistribution layer 152, and/or the third redistribution layer 153), and/or a corresponding dielectric body (such as the first dielectric body 161 and/or the second dielectric body 162).

It is worth noting that similar reference numerals are used for the singulated devices after the singulation process. For example, the carrier 110 (shown in FIG. 1H) may be the carrier 110 (shown in FIG. 1I) after the singulation process, the first dielectric body 161 (shown in FIG. 1H) may be the first dielectric body 161 (shown in FIG. 1I) after the singulation process., the first redistribution layer 151 (shown in FIG. 1H) may be the first redistribution layer 151 (shown in FIG. 1I) after the singulation process, and the conductive terminals 173 (if these conductive terminals 173 were already present before the singulation process) may be the conductive terminals 173 (shown in FIG. 1I), and so on. Other singulated devices follow the same reference numeral rule mentioned above and are not repeated or specifically shown here.

It is worth noting that the disclosure does not limit the order of disposing the conductive terminals 173 and the singulation process.

In addition, after the singulation process is completed, the singulated carrier 110 may be the same or similar to the chip in terms of structure, appearance, and/or corresponding functions and purposes. In order to make the processes and corresponding structures echo and differentiate from each other, the singulated carrier 110 is directly referred as a first chip. Also, the first chip may still refer to the same reference numeral (that, the first chip 110) in the drawings.

For example, the unsingulated carrier 110 may be a silicon wafer having corresponding device regions and having scribe lines that separate the device regions. Moreover, the singulation process may be performed corresponding to the scribe lines, so that each singulated structure (such as the package structure 100) includes a corresponding first chip 110.

In an embodiment, after the aforementioned singulation process is completed, the side wall of the redistribution layer (such as the first redistribution layer 151, the second redistribution layer 152, and/or the third redistribution layer 153), the side wall of the dielectric body (such as the first dielectric body 161 and/or the second dielectric body 162), and the side wall of the first chip 110 may be flush/aligned with each other.

After the above steps, the production of the package structure 100 of an embodiment may be roughly completed.

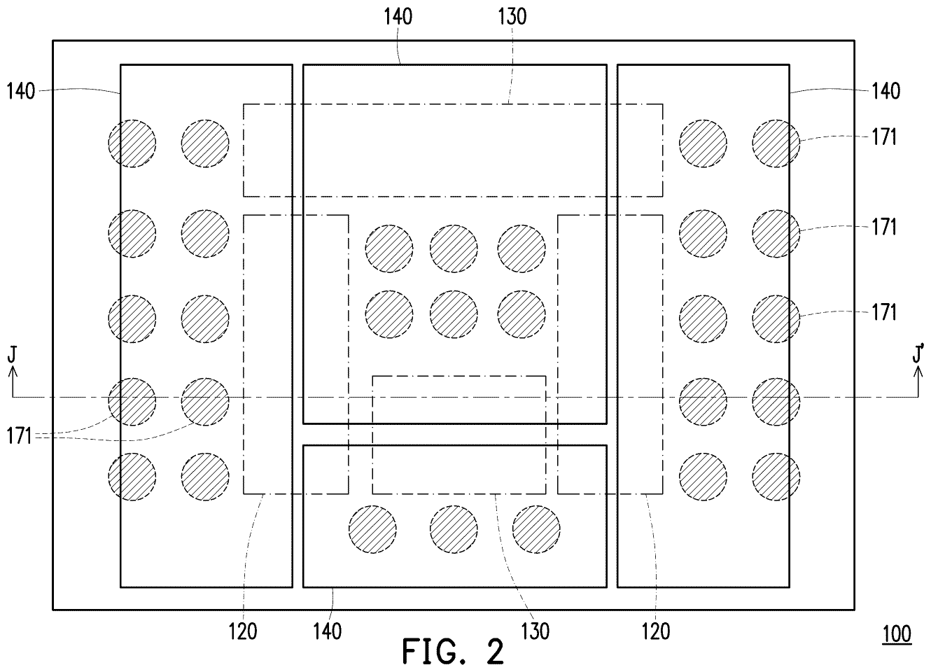

FIG. 1J is a schematic partial cross-sectional view of a package structure according to an embodiment of the disclosure. FIG. 1K is a schematic partial cross-sectional view of a package structure according to an embodiment of the disclosure. FIG. 2 is a partial top view of a package structure according to an embodiment of the disclosure. For example, FIG. 1K may be an enlarged view corresponding to a region R1 in FIG. 1J. For example, FIG. 1J may be a schematic cross-sectional view corresponding to a J-J′ line in FIG. 2. It is also worth noting that the package structure 100 in FIG. 1J, FIG. 1K, and FIG. 2 may be manufactured by the manufacturing method shown in FIG. 1A to FIG. 1I or correspondingly described, but the disclosure is not limited thereto.

Referring to FIG. 1J, FIG. 1K, and FIG. 2, the package structure 100 includes the first chip 110, at least one second chip 120, the fourth chips 140, the first redistribution layer 151, the second redistribution layer 152, the third redistribution layer 153, the first dielectric body 161, the second dielectric body 162, and the conductive members 171. The first chip 110 is disposed between the first redistribution layer 151 and the third redistribution layer 153. The conductive member 171 is disposed between the first redistribution layer 151 and the second redistribution layer 152, and a corresponding circuit in the second redistribution layer 152 is electrically connected to the first chip 110 (for example, the conductive through via 117 of the first chip 110 or the circuit therein) by a corresponding conductive member 171 and a corresponding circuit in the first redistribution layer 151. The second redistribution layer 152 is disposed between the second chip 120 and the fourth chip 140. At least two of the fourth chips 140 are electrically connected to a corresponding second chip 120 by a corresponding circuit in the second redistribution layer 152. The first dielectric body 161 at least covers the second chip 120, the first redistribution layer 151, the second redistribution layer 152, and the conductive member 171. The second dielectric body 162 at least covers the second redistribution layer 152.

In an embodiment, the first dielectric body 161 and the second dielectric body 162 are separated from each other at least by the second redistribution layer 152.

In an embodiment, the package structure 100 further includes at least one third chip 130. The third chip 130 is disposed between the first redistribution layer 151 and the second redistribution layer 152; and/or, the second redistribution layer 152 is disposed between the third chip 130 and the fourth chip 140.

In an embodiment, the package structure 100 further includes a filling layer 164. The filling layer 164 is at least disposed between the fourth chip 140 and the second redistribution layer 152; and/or the filling layer 164 laterally covers a portion of the fourth chip 140. The second dielectric body 162 may cover a portion of the filling layer 164. In an embodiment, the second dielectric body 162 may expose a portion of another portion of the filling layer 164 that is not covered by the second dielectric body 162.

In an embodiment, the first chip 110 may have the conductive through via 117. A corresponding circuit in the first redistribution layer 151 and a corresponding circuit in the third redistribution layer 153 may be electrically connected by a corresponding conductive through via 117 in the first chip 110.

In an embodiment, in a direction parallel to a thickness of the package structure 100, the conductive member 171 has a first height H1, the chip connector 125 of the second chip 120 has a second height H2, and the conductive through via 117 of the first chip 110 has a third height H3. The first height H1 is greater than or substantially equal to the third height H3; and/or, the third height H3 is greater than or substantially equal to the second height H2. In an embodiment, a height (for example, corresponding to the first height H1) of any conductive member 171 is greater than or substantially equal to a height (for example, corresponding to the third height H3) of any conductive through via 117 in the first chip 110; and/or, a height (for example, corresponding to the third height H3) of any conductive through via 117 in the first chip 110 is greater than or substantially equal to a height (for example, corresponding to the second height H2) of any chip connector 125 in any second chip 120.

In an embodiment, in the direction perpendicular to the thickness of the package structure 100, the conductive member 171 has a first width W1, the chip connector 125 of the second chip 120 has a second width W2, the chip connector 145 of the fourth chip 140 has a fourth width W4, and a conductive region of the conductive through via 117 of the first chip 110 has a third width W3. The first width W1 is greater than or substantially equal to the second width W2; and/or, the second width W2 is greater than or substantially equal to the third width W3. The first width W1 is greater than or substantially equal to the fourth width W4; and/or, the fourth width W4 is greater than or substantially equal to the third width W3.

In an embodiment, the second width W2 may be substantially the same or similar to the fourth width W4 (for example, a ratio is between 95% and 105%), but the disclosure is not limited thereto.

In an embodiment, a width (for example, corresponding to the first width W1) of any conductive member 171 is greater than or substantially equal to a width (for example, corresponding to the second width W2) of any chip connector 125 in any second chip 120, a width (for example, corresponding to the first width W1) of any conductive member 171 is greater than or substantially equal to a width (for example, corresponding to the fourth width W4) of any chip connector 145 in any fourth chip 140; and/or, a width of any chip connector 125 in any second chip 120 (for example, corresponding to the second width W2) is greater than or substantially equal to a width (for example, corresponding to the third width W3) of any conductive through via 117 in the first chip 110.

In an embodiment, all fourth chips 140 have a corresponding fourth projection area on a plane (e.g., each fourth chip 140 has a corresponding single projected area, and the fourth projected area is the sum of the aforementioned single projected areas), all second chip(s) 120 has/have a corresponding second projection area on the plane (e.g., there is only one second chip 120, and the second projected area is the single projected area of the single second chip 120; either or, there are a plurality of second chips 120, each second chip 120 has a corresponding single projected area, and the second projected area is the sum of the aforementioned single projected areas), and the thickness direction of the package structure 100 is perpendicular to the plane (for example, the plane shown in FIG. 2). The fourth projection area is basically larger than the second projection area.

In an embodiment, all third chip(s) 130 has/have a corresponding third projection area on the plane (e.g., there is only one third chip 130, and the third projected area is the single projected area of the single third chip 130; either or, there are a plurality of third chips 130, each third chip 130 has a corresponding single projected area, and the third projected area is the sum of the aforementioned single projected areas), and the fourth projection area is substantially larger than a sum of the second projection area and the third projection area.

In an embodiment, the package structure 100 has a corresponding total projection area on the plane. Moreover, the fourth projection area account for approximately 75% to 95% of the total projection area; the second projection area account for approximately 1% to 10% of the total projection area, and/or, the sum of the second projection area and the third projection area accounts for approximately 5% to 30% of the total projection area.

In an embodiment, during the manufacturing process of the package structure 100, the carrier and/or the fourth chip 140 used to form the first chip 110 may be moderately thinned. Moreover, before or during thinning, the carrier and/or the fourth chip 140 have been well fixed, and/or a corresponding structure has a relatively thick thickness. In this way, the carrier and/or the fourth chip 140 used to form the first chip 110 may be easily thinned to an appropriate thickness, thereby reducing the overall thickness of the package structure 100.

In an embodiment, since the conductive member 171 is disposed on the first chip 110, and may be electrically connected to the first chip 110 by the first redistribution layer 151 disposed on the first chip 110. In this way, the overall thickness of the package structure 100 may be reduced. Moreover, no conductive member different from the conductive member 171 (not shown because there is none) is disposed side by side with the first chip 110. Disposing the conductive member 171 on the first chip 110 may increase the number and/or density of the conductive members 171 within a aspect ratio limit. In this way, the manufacturing yield of the package structure 100 may be improved, and/or the package structure 100 may have good quality.

In an embodiment, the first chip 110 may be an active chip. For example, the first chip 110 may be an active power delivery chip, and may at least be powered by active devices (or further including corresponding passive devices or appropriate circuits) to perform voltage regulation, rectification, shunting, switching, frequency modulation, phase change, other appropriate power regulation or power management on the electric energy input thereto.

In an embodiment, the first chip 110 may be a passive chip. For example, the first chip 110 may perform voltage reduction, rectification, shunting, or other appropriate power management on the power input thereto by the passive device (such as the resistor or the capacitor) or appropriate circuits.

In an embodiment in which the first chip 110 is the active power deliver chip, one (such as a conductive member 171′) of the conductive members 171 may be connected to the conductive through vias 117 in the first chip 110 by the corresponding circuits in the first redistribution layer 151, and the aforementioned conductive member 171 may serve as the power delivery or the ground source of the corresponding fourth chip 140. In this way, when the package structure 100 is operating, good power transmission quality may be achieved. However, it is worth noting that if necessary, other conductive members 171 that are the same or similar to the conductive member 171′ may also be used for signal transmission. In an embodiment, one (for example, the conductive member 171′) of the conductive members 171 may overlap with the conductive through vias 117 electrically connected thereto.

In an embodiment, the number of fourth chips 140 may be multiple. In an embodiment, the fourth chips 140 may be dies, chiplet, packaged chips, or stacked chip packages with the same or different functions or application-specific integrated circuit (ASIC), but the disclosure is not limited thereto. For example, one of the fourth chips 140 may be a dynamic random access memory (DRAM), a static random access memory (SRAM), or a high bandwidth memory (HBM) or other similar memory chips, but the disclosure is not limited thereto. For example, one of the fourth chips 140 may be an application-specific integrated circuit (ASIC), an application processor (AP), a system on chip (SoC), a network-on-chip (NoC) or other similar high performance computing (HPC) chips, but the disclosure is not limited thereto. In an embodiment, two of the fourth chips 140 may be heterogeneous chips or homogenous chips.

In an embodiment, the first chip 110 and the fourth chip 140 may be disposed on opposite sides of the package structure 100 respectively. Taking FIG. 1J as an example, the first chip 110 is disposed on a lower side of the package structure 100, and the fourth chip 140 is disposed on an upper side of the package structure 100. In this way, when the package structure 100 is operating, the heat source generated may be dispersed, thereby improving the stability of the package structure 100 during operation, and/or improving the corresponding heat dissipation efficiency.

In an embodiment, signals between different fourth chips 140 are transmitted by the corresponding circuits in the corresponding second chip 120. In this way, the corresponding signal transmission quality and/or signal transmission efficiency may be improved.

In an embodiment, in the thickness direction of the package structure 100, all chips (such as the second chip 120 and the third chip 130) between the first chip 110 and the fourth chip 140 are not active chips. For example, the second chip 120 is the bridge chip for signal transmission, and the third chip 130 (if any) is the dummy chip. That is, when the package structure 100 is operating, the second chip 120 and/or the third chip 130 are hardly regarded as heat sources, but the silicon material constituting the second chip 120 and/or the third chip 130 may still be a good thermal conductor. In this way, when the package structure 100 is operating, the corresponding heat dissipation efficiency may be improved, and the stability of the package structure 100 during operation may be improved.

In summary, the package structure of the disclosure may have a smaller size. Moreover, the package structure may have better quality or performance by the arrangement of the corresponding devices/components (such as chips, redistribution layers, dielectric bodies, and conductive members).

What is claimed is:

1. A package structure, comprising a first chip, at least one second chip, a plurality of fourth chips, a first redistribution layer, a second redistribution layer, a third redistribution layer, a first dielectric body, a second dielectric body, and a conductive member, wherein:
the first chip is disposed between the first redistribution layer and the third redistribution layer;
the conductive member is disposed between the first redistribution layer and the second redistribution layer, and the second redistribution layer is electrically connected to the first chip by the conductive member and the first redistribution layer;
the second redistribution layer is disposed between the second chip and the fourth chip;
at least two of the plurality of fourth chips are electrically connected to each other by the second redistribution layer and the second chip;
the first dielectric body at least covers the second chip, the first redistribution layer, the second redistribution layer, and the conductive member; and
the second dielectric body at least covers the second redistribution layer.

2. The package structure according to claim 1, wherein the first dielectric body and the second dielectric body are separated from each other at least by the second redistribution layer.

3. The package structure according to claim 1, wherein the package structure further comprises: at least one third chip, wherein:
the third chip is disposed between the first redistribution layer and the second redistribution layer; and/or
the second redistribution layer is disposed between the third chip and the fourth chip.

4. The package structure according to claim 3, wherein the third chip is a dummy chip.

5. The package structure according to claim 1, wherein the package structure further comprises: a filling layer, wherein:
the filling layer is disposed at least between the fourth chip and the second redistribution layer; and/or
the filling layer laterally covers a portion of the fourth chip.

6. The package structure according to claim 5, wherein the second dielectric body exposes a portion of the filling layer.

7. The package structure according to claim 1, wherein the first chip has a conductive through via, and the first redistribution layer and the third redistribution layer are electrically connected by the conductive through via of the first chip.

8. The package structure according to claim 1, wherein the conductive member has a first height, a chip connector of the second chip has a second height, and a conductive through via of the first chip has a third height, and wherein:
the first height is greater than or substantially equal to the third height; and/or
the third height is greater than or substantially equal to the second height.

9. The package structure according to claim 1, wherein in a direction perpendicular to a thickness of the package structure, the conductive member has a first width, a chip connector of the second chip or the fourth chip has a connector width, and a conductive through via of the first chip has a third width, and wherein:
the first width is greater than or substantially equal to the connector width; and/or
the connector width is greater than or substantially equal to the third width.

10. The package structure according to claim 1, wherein the first chip comprises a plurality of conductive through vias, and the conductive member overlaps with or is electrically connected to the plurality of conductive through vias.

11. The package structure according to claim 1, a thickness direction of the package structure is perpendicular to a plane, all of the plurality of fourth chips has a corresponding fourth projection area on the plane, all of the at least one second chip has a corresponding second projection area on the plane, and the fourth projection area is greater than or substantially equal to the second projection area.

12. The package structure according to claim 11, wherein the package structure further comprises: at least one third chip, wherein:
the third chip is disposed between the first redistribution layer and the second redistribution layer, and/or the second redistribution layer is disposed between the third chip and the fourth chip; and
all of the at least one third chip has a corresponding third projection area on the plane, and the fourth projection area is greater than or substantially equal to a sum of the second projection area and the third projection area.

13. A manufacturing method of a package structure, comprising:
providing a carrier;
forming a first redistribution layer on the carrier;
disposing at least one second chip on the first redistribution layer;
forming a first dielectric body;
forming a second redistribution layer on the first dielectric body;
disposing a plurality of fourth chips on the second redistribution layer;
forming a second dielectric body; and
cutting the carrier to form a first chip, wherein:
the first chip is disposed between the first redistribution layer and a third redistribution layer;
a conductive member is disposed between the first redistribution layer and the second redistribution layer, and the second redistribution layer is electrically connected to the first chip by the conductive member and the first redistribution layer;
the second redistribution layer is disposed between the second chip and the fourth chip;
at least two of the plurality of fourth chips are electrically connected to each other by the second redistribution layer and the second chip;
the first dielectric body at least covers the second chip, the first redistribution layer, the second redistribution layer, and the conductive member; and
the second dielectric body at least covers the second redistribution layer.

14. The manufacturing method of the package structure according to claim 13 further comprising:
forming the conductive member on the first redistribution layer.

15. The manufacturing method of the package structure according to claim 13 further comprising:
forming the third redistribution layer after forming the second dielectric body.

16. The manufacturing method of the package structure according to claim 13 further comprising: thinning the plurality of the fourth chips.

17. The manufacturing method of the package structure according claim 13 further comprising: thinning the carrier.
